(19) United States
(12) Patent Application Publication
(10) Pub. No.: US 2007/0171620 A1
(43) Pub. Date: Jul. 26, 2007

(54) Structure of USB connector of mini portable flash memory drive

(76) Inventor: Yun-Hsiu Lee, Taipei Hsien (TW)

Correspondence Address: Troxell Law Office Pllc;Suite 1404, 5205 Leesburg Pike, Falls Church, VA, 22041, US

(21) Appl. No.: 11/335,643

(22) Filed: Jan. 20, 2006

(51) Int. Cl. H05K 1/14

(52) U.S. Cl. 361/737

(57) ABSTRACT

A structure of USB connector of mini portable flash memory drive comprises of a plastic body, a microchip PCB and a steel enclosure. Plug the plastic body where is installed a microchip PCB into the steel enclosure. The steel enclosure features an oblong sheath, a stamped connector on its top as well as convex points and concave ribs on its both flanks. Besides, the stamped connector has a L-typed shield at its opening. A plastic body has groove on its upper part for buckling it to buttons of the steel enclosure. A microchip PCB installed inside of the plastic body. While plugging the plastic body containing a microchip PCB into the steel enclosure for assembling, all related elements is tightly fixed at every position (up and down, rear and front, right and left). Dimensions of this assembly unit shall be in conformity with USB requirements.

### BACKGROUND OF THE INVENTION

(a) Field of the Invention

The present invention refers to a structure of USB connector of mini portable flash memory drive, and more particularly, to a connector of a mini portable flash memory drive that adopts universal serial bus (USB) for data transmission. Besides, all elements thereof are of precise placement and tightly fixed in a limited space.

(b) Description of the Prior Art

Along with the dynamic changes in computer technology, many documents, music, images even movies are transformed into digital format. In order to carry those digital content wherever, there has been an arrival of various storage devices on the market. The popular ones among those are optical disk, floppy disk, portable hard disk and flash memory drive.

Amongst them, there are two types of optical disk including CD and DVD that are readable by a common optical disk drive (i.e. CD-ROM or DVD-ROM). However, writing data into them shall require another device (CD-RAM or DVD-RAM).

Due to its limited capacity, the floppy disk has the least storage space applicable for the popular MP3 music file. The floppy disk with usual capacity of 1.44 MB can hardly load any popular MP3 music, size of which is usually around 3 to 5 MB after file compression. Of course, there exist such floppy disks of large storage capacity as ZIP or MO that may load the MP3 music file. But they also require special device to read and write files.

In comparison with the floppy disk, the portable hard disk has larger capacity in storage and higher speed in data transmission. The portable hard disk is to install a hard disk used by a notebook or desktop computer in an enclosure where has a built-in interface circuit board connecting the hard disk for data transmission with the computer. The user only needs to plug a data transmission cable of portable hard disk into a connecting port of computer to read and write data from the computer to portable hard disk or, vice versa. Though the portable hard disk has advantages such as large storage capacity, high transmission speed and the lowest cost at each storage unit, it is less mobile because of its comparatively large size.

In view of the forgoing deficiencies, the portable flash memory drive is thus invented. It has high speed in data transmission and compact size but a medium capacity in storage. High cost at storage unit is the only challenge that a portable flash memory drive encounters. However, this is overcome by advancement of flash memory technology, which further reduces production cost and size of flash memory. As a consequence, popularity of the portable flash memory drive is enormously increasing. Besides, the USB plug (two specifications as USB1.1 and USB2.0 available) is widely applied on computers. The portable flash memory drive thus needs to adopt universal serial bus (USB) to bridge its communication with the computer. Naturally, an USB connector is indispensable to a portable flash memory drive whichever. FIG. 1 shows a common portable flash memory drive that comprises a plastic enclosure a1, a circuit board a2 as well as a connector a3 connecting to the circuit board. The connector a3 is composed of an external electric-conduction steel shell a31 and golden fingers a32 of internal circuit board a2. Bridging communication between flash memory and computer, the USB connector is doubtless an indispensable element to the portable flash memory drive a. In view of the importance of USB connector to a portable flash memory drive, objective of this invention is to address a new structure of USB connector of mini portable flash memory drive that minimizes the size of whole assembly unit and simplifies the construction of it. Design of this invention is to plug a plastic body that contains a microchip printed circuit board (PCB) into a steel enclosure by buckling its groove to the buttons thereof. In this way, the microchip PCB inside of the plastic body is mostly encased by the steel enclosure. This design thus effectively minimizes the size and further simplifies the construction of a portable flash memory drive.

### SUMMARY OF THE INVENTION

Objective of this invention is to provide a structure of USB connector of mini portable flash memory drive that further reduces the size and simplifies the structure of a portable flash memory drive. Design of this invention ensures all elements are tightly fixed at each position (up and down, rear and front, right and left) while assembling. Besides, dimensions of this assembly unit are in conformity with USB requirements.

To achieve the foregoing objective, the present invention related to a structure of USB connector of mini portable flash memory drive comprising of a plastic body, a microchip PCB and a steel enclosure. The microchip PCB is installed inside of the plastic body, which can be plugged into the steel enclosure. Amongst all, the steel enclosure is an oblong sheath that features a stamped connector on its top and convex points and concave ribs on both its flanks. Besides, there is a L-typed shield at the opening of the stamped connector. Groove on the upper part of plastic body buckles to buttons of the steel enclosure while plugging the plastic body therein.

To assemble the foregoing elements into an assembly unit, plug the plastic body with a microchip PCB inside into the steel enclosure from rear end thereof. Buckle afterwards groove of the plastic body to buttons of the steel enclosure. In this way, each element of the assembly unit is tightly fixed at every position (up and down, front and rear, left and right). Besides, dimensions of this assembly unit shall be in conformity with USB requirements. While plugging the plastic body into the steel enclosure, make sure that its front hits the L-typed shield at the opening of the stamped connector. Besides, concave ribs on both flanks of steel enclosure are to fill in the gap between plastic body and microchip PCB. The key to minimize the size and simplify the construction of a portable flash memory drive, objective of this invention, is that the microchip PCB installed inside of plastic body is mostly encased in the steel enclosure. Besides, the connector of this invention is unified but rear end of plastic body is extensive, which can be enclosed, opened or other in other forms. The plastic body also has convex points that ensure the 2-section flap stationed in fixed position.

### BRIEF DESCRIPTION OF THE DRAWINGS

FIG. 1 is the diagram of conventional portable flash memory drive.

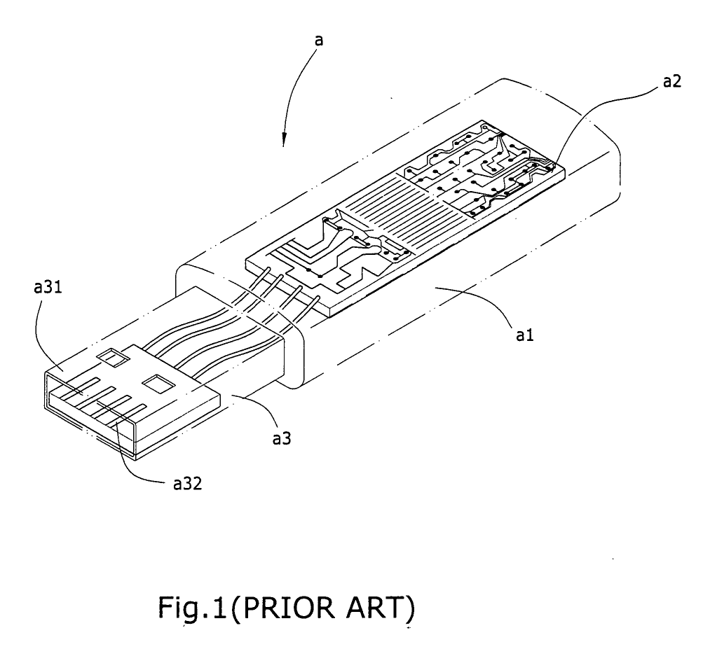

FIG. 2 is the diagram of this invention.

FIG. 3 is the cross-sectional view of this invention in assembly.

FIG. 4 is the embodiment of joining a rotatory flap to this invention.

FIG. 5 is the usage of the rotatory flap.

FIG. 6 is this invention hosted by the rotatory flap.

### DETAILED DESCRIPTION OF THE PREFERRED EMBODIMENT

Further structure, assembly and features of this invention will be better understood from the detailed description and drawings that follow a better embodiment of the disclosed invention are illustrated by ways of example below:

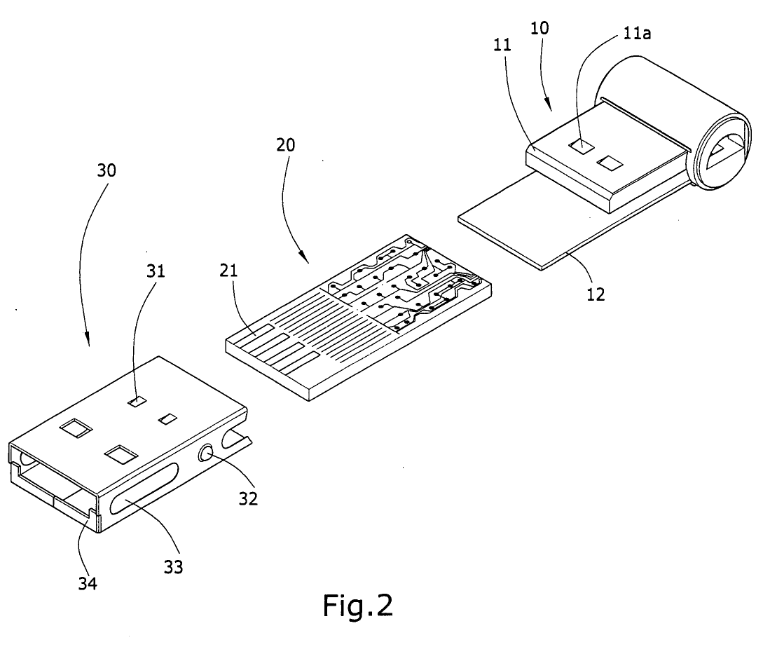

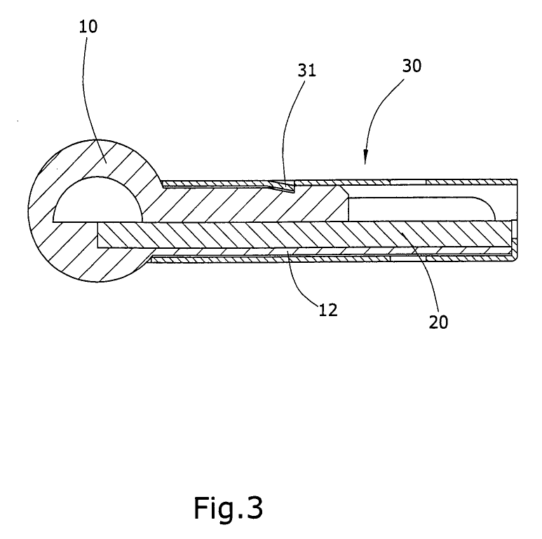

Referring to FIGS. 2 and 3, the structure of USB connector of mini portable flash memory drive of this invention is composed of a plastic body 10, a microchip PCB20 and a steel enclosure 30. The microchip PCB20 is installed in the plastic body 10, which can be plugged into the steel enclosure 30.

The plastic body 10 therein is made by injection in mold and flanks of which are similar to a U form clip. Its upper deck 11 where has groove 11a buckling to button 31 of stamped connector is shorter than its lower deck 12.

The microchip PCB20 has a flash memory for storage and four golden fingers 21 for connection with USB connector.

The steel enclosure 30, an oblong sheath, has stamped button 31 on the upper part as well as convex point 32 and concave rib 33 on both flanks. Besides, there is a L-typed shield 34 on its opening.

While assembling, plug the plastic body 10 with the microchip PCB20 inside into the steel enclosure 30 from the rear end thereof. Make sure that the front end of plastic body 10 hits the L-typed shield 34. The concave rib 33 on the flanks of steel enclosure 30 is to fill in the gap between the plastic body 10 and microchip PCB20. Buckle the button 31 of steel enclosure 30 to groove 11a of plastic body 10.

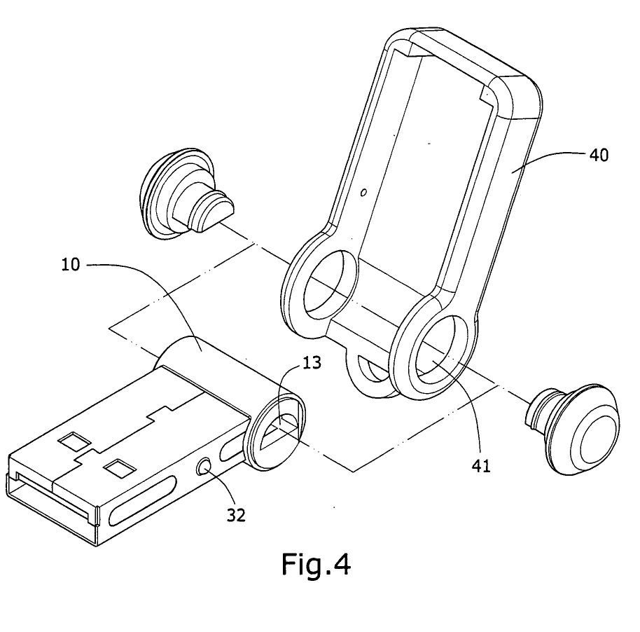

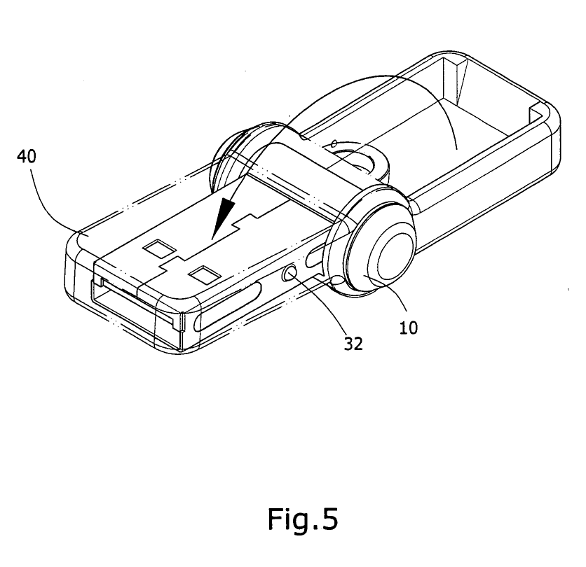

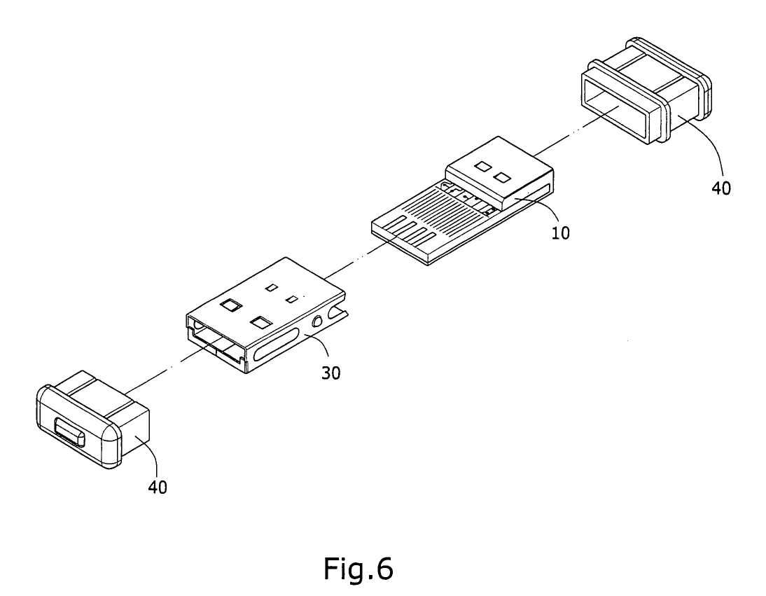

Referring to FIGS. 4 and 5 shows how to install the rotatory flap 40 on the mini portable flash memory drive. The rotatory flap 40 has two sections: cap and case. The plastic body 10 has a pivot 13 at its rear part where joins the rotatory flap 40 by screwing bolts through hole 41. The convex points 32 on the flanks of steel enclosure are to station the rotatory flap 40 in fixed position. Referring to FIG. 6, the rotatory flap 40 can host the entire assembly unit of this invention: steel enclosure 30 in its cap and plastic body 10 in its case.

The foregoing embodiments are among those feasible ones of this invention that performs the function to prevent the connector of steel enclosure from damages by pressure or water. Anyhow, other embodiments that perform the said function shall not be recited lest confining embodiment of this invention to a limited scope. Hence, other embodiment whichever performs the said function or equivalents shall be regarded as part of this invention.

To sum up, the structure of USB connector of mini portable flash memory drive of this invention is to further reduce the size and simplify the structure of a portable flash memory drive without compromising its fulfillment of USB requirements and steady placement of each element. This invention is practical and advanced. Submission of this invention is to register the patents thereof for its original solution according to the patent law.

1. (canceled)

2. The USB connector structure for the mini portable flash memory drive of claim 4, wherein the plastic body at its rear end has a pivot for installing a rotatory flap screwed to holes aligning with the pivot.

3. The USB connector structure for the mini portable flash memory drive of claim 4, further comprising a rotatory flap of two sections including a cap that encases the steel enclosure and a case that encases the plastic body.

4. A USB connector structure for a mini portable flash memory drive comprising a plastic body, a microchip PCB and a steel enclosure; the plastic body having a microchip PCB installed into the steel enclosure; the steel enclosure being shaped as an oblong sheath, the steel enclosure having on a top surface at least one button extending into the interior of the steel enclosure and convex points and concave ribs on the sides of the steel enclosure; the steel enclosure further comprising an L-shaped shield at an opening of the steel enclosure; the plastic body having at least one indented groove configured to buckle to the at least one button of the steel enclosure.
